(19) United States
(12) Patent Application Publication
(10) Pub. No.: US 2026/0305216 A1
(43) Pub. Date: Oct. 1, 2026

(54) DUAL SIDE STEALTH DICING FOR FORMING MEMORY CHIPS

(71) Applicant: Micron Technology, Inc., Boise, ID (US)

(72) Inventors: Ankur Harish Shah, Singapore (SG); Liang Chun FU, Taiwan (TW); Mei Wen Luken, Taiwan (TW); Harjashan Veer Singh, Taiwan (TW); Wen How Sim, Singapore (SG)

(21) Appl. No.: 19/578,796

(22) Filed: Mar. 25, 2026

Related U.S. Application Data
(60) Provisional application No. 63/781,811, filed on Apr. 1, 2025.

(51) Int. Cl. H10P 58/00; H10P 52/00

(52) U.S. Cl. CPC H10P 58/22; H10P 52/00

(57) ABSTRACT

Methods, systems, and devices associated with use of dual side stealth dicing for forming memory chips are described. A manufacturing process in which stealth dicing operations may be performed multiple times may be adopted. For example, a first stealth dicing operation may be performed on a first semiconductor wafer of a semiconductor wafer stack. A reduction operation may be performed on the first semiconductor wafer to remove a portion of the wafer, the reduced stack may be flipped over and mounted on die-attach film (DAF). A second stealth dicing operation may then be performed on a second semiconductor wafer of the semiconductor wafer stack, such that the semiconductor wafer stack may be fully cut through and singulated.

### CROSS REFERENCE

The present Application for Patent claims priority to U.S. Patent Application No. 63/781,811 by Shah et al., entitled “DUAL SIDE STEALTH DICING FOR FORMING MEMORY CHIPS,” filed April 1, 2025, which is assigned to the assignee hereof, and which is expressly incorporated by reference in its entirety herein.

### TECHNICAL FIELD

The following relates to one or more systems for memory, including dual side stealth dicing for forming memory chips.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports dual side stealth dicing for forming memory chips in accordance with examples as disclosed herein.

FIGS. 2A through 2F show example processing steps that support dual side stealth dicing for forming memory chips in accordance with examples as disclosed herein.

FIG. 3 shows a flowchart illustrating a method or methods that support dual side stealth dicing for forming memory chips in accordance with examples as disclosed herein.

### DETAILED DESCRIPTION

Various techniques have been implemented to decrease the packaging size (e.g., a physical size) of memory devices. In some cases, to decrease the packaging size of memory devices, a memory device may be manufactured to include a stacked memory structure where multiple semiconductor wafers are stacked (e.g., stacked on top of one another). To manufacture the stacked memory devices, various operations may be performed to deposit and bond multiple layers together, and dicing processes may be performed on the bonded layers to singulate the layers into memory chips (e.g., individual stacked memory structures). However, conventional dicing processes, such as blade dicing, may be difficult to implement due to inefficiencies and potential ineffectiveness associated with cutting through multiple layers of material (e.g., splintering of materials, incomplete cuts, crushing of layers). Additionally, some stacked memory architectures may include multiple types of memory within a single structure, and each type of memory may be associated with different crystal structures and varying wafer thicknesses. An increase in thickness and density of a memory structure associated with use of multiple memory types in a single memory architecture may result in additional difficulties when performing blade dicing operations (e.g., it may be difficult to cut through a stacked memory structure using blade dicing techniques).

To reduce memory device packaging sizes while increasing effectiveness of singulation operations, a manufacturing process in which stealth dicing operations may be performed multiple times may be implemented. For example, a first stealth dicing operation may be performed on a first semiconductor wafer of a semiconductor wafer stack. An operation may be performed on the first semiconductor wafer to remove a portion of the wafer, and the reduced stack may be rotated (e.g., flipped over) and mounted on die-attach film (DAF) (e.g., the first semiconductor wafer may be mounted on the DAF). A second stealth dicing operation may then be performed on a second semiconductor wafer of the semiconductor wafer stack, such that the semiconductor wafer stack may be singulated (e.g., formed into individual memory chips). Performing multiple stealth dicing operations on semiconductor wafer stack to singulate memory chips may enable various combinations of memory within a single memory chip, while also increasing efficiency and effectiveness of chip singulation operations.

In addition to applicability in memory systems as described herein, use of dual side stealth dicing in forming memory chips may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by eliminating production processes, which may result in lowered production emissions and reduced electronic waste, among other benefits.

Features of the disclosure are illustrated and described in the context of systems and architectures. Features of the disclosure are further illustrated and described in the context of layouts and flowcharts.

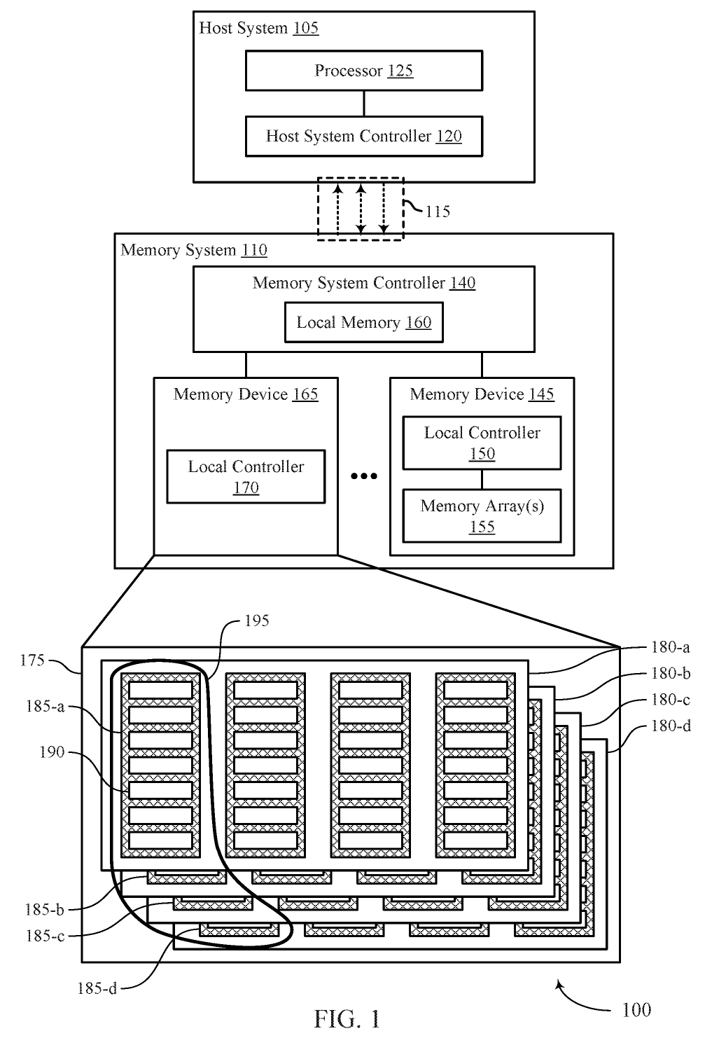

FIG. 1 shows an example of a system 100 that supports dual side stealth dicing for forming memory chips in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, provide data stored in a memory device 165 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, a local controller 170 of a memory device 165, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

The memory system 110 may include one or more memory devices 165. A memory device 165 may include one or more memory arrays of any type of memory cells (e.g., non-volatile memory cells, volatile memory cells, or any combination thereof). Although two memory devices 165-a and 165-b are shown in the example of FIG. 1, the memory system 110 may include any quantity of memory devices 165. Further, if the memory system 110 includes more than one memory device 165, different memory devices 165 within the memory system 110 may include the same or different types of memory cells.

The memory system controller 140 may be coupled with and communicate with the host system 105 (e.g., via the physical host interface) and may be an example of a controller or control component configured to cause the memory system 110 to perform various operations in accordance with examples as described herein. The memory system controller 140 may also be coupled with and communicate with memory devices 165 to perform operations such as reading data, writing data, erasing data, or refreshing data at a memory device 165—among other such operations—which may generically be referred to as access operations. In some cases, the memory system controller 140 may receive commands from the host system 105 and communicate with one or more memory devices 165 to execute such commands (e.g., at memory arrays within the one or more memory devices 165). For example, the memory system controller 140 may receive commands or operations from the host system 105 and may convert the commands or operations into instructions or appropriate commands to achieve the desired access of the memory devices 165. In some cases, the memory system controller 140 may exchange data with the host system 105 and with one or more memory devices 165 (e.g., in response to or otherwise in association with commands from the host system 105). For example, the memory system controller 140 may convert responses (e.g., data packets or other signals) associated with the memory devices 165 into corresponding signals for the host system 105.

The memory system controller 140 may be configured for other operations associated with the memory devices 165. For example, the memory system controller 140 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 165.

The memory system controller 140 may include hardware such as one or more integrated circuits or discrete components, a buffer memory, or a combination thereof. The hardware may include circuitry with dedicated (e.g., hard-coded) logic to perform the operations ascribed herein to the memory system controller 140. The memory system controller 140 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 140 may also include a local memory 160. In some cases, the local memory 160 may include read-only memory (ROM) or other memory that may store operating code (e.g., executable instructions) executable by the memory system controller 140 to perform functions ascribed herein to the memory system controller 140. In some cases, the local memory 160 may additionally, or alternatively, include static random access memory (SRAM) or other memory that may be used by the memory system controller 140 for internal storage or calculations, for example, related to the functions ascribed herein to the memory system controller 140. Additionally, or alternatively, the local memory 160 may serve as a cache for the memory system controller 140. For example, data may be stored in the local memory 160 if read from or written to a memory device 165, and the data may be available within the local memory 160 for subsequent retrieval for or manipulation (e.g., updating) by the host system 105 (e.g., with reduced latency relative to a memory device 165) in accordance with a cache policy.

Although the example of the memory system 110 in FIG. 1 has been illustrated as including the memory system controller 140, in some cases, a memory system 110 may not include a memory system controller 140. For example, the memory system 110 may additionally, or alternatively, rely on an external controller (e.g., implemented by the host system 105) or one or more local controllers 170, which may be internal to memory devices 165, respectively, to perform the functions ascribed herein to the memory system controller 140. In general, one or more functions ascribed herein to the memory system controller 140 may, in some cases, be performed instead by the host system 105, a local controller 170, or any combination thereof. In some cases, a memory device 165 that is managed at least in part by a memory system controller 140 may be referred to as a managed memory device. An example of a managed memory device is a managed NAND (MNAND) device.

A memory device 165 may include one or more arrays of non-volatile memory cells. For example, a memory device 165 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 165 may include one or more arrays of volatile memory cells. For example, a memory device 165 may include RAM memory cells, such as dynamic RAM (DRAM) memory cells and synchronous DRAM (SDRAM) memory cells.

In some examples, a memory device 165 may include (e.g., on the same die, within the same package) a local controller 170, which may execute operations on one or more memory cells of the respective memory device 165. A local controller 170 may operate in conjunction with a memory system controller 140 or may perform one or more functions ascribed herein to the memory system controller 140. For example, as illustrated in FIG. 1, a memory device 165-a may include a local controller 170-a and a memory device 165-b may include a local controller 170-b. A local controller 170 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 165 may be or include a NAND device (e.g., NAND flash device). A memory device 165 may be or include a die 175 (e.g., a memory die). For example, in some cases, a memory device 165 may be a package that includes one or more dies 175. A die 175 may, in some examples, be a piece of electronics-grade semiconductor cut from a wafer (e.g., a silicon die cut from a silicon wafer). Each die 175 may include one or more planes 180, and each plane 180 may include a respective set of blocks 185, where each block 185 may include a respective set of pages 190, and each page 190 may include a set of memory cells.

In some cases, a NAND memory device 165 may include memory cells configured to each store one bit of information, which may be referred to as single level cells (SLCs). Additionally, or alternatively, a NAND memory device 165 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 180 may refer to groups of blocks 185 and, in some cases, concurrent operations may be performed on different planes 180. For example, concurrent operations may be performed on memory cells within different blocks 185 so long as the different blocks 185 are in different planes 180. In some cases, an individual block 185 may be referred to as a physical block, and a virtual block 195 may refer to a group of blocks 185 within which concurrent operations may occur. For example, concurrent operations may be performed on blocks 185-a, 185-b, 185-c, and 185-d that are within planes 180-a, 180-b, 180-c, and 180-d, respectively, and blocks 185-a, 185-b, 185-c, and 185-d may be collectively referred to as a virtual block 195. In some cases, a virtual block may include blocks 185 from different memory devices 165 (e.g., including blocks in one or more planes of memory device 165-a and memory device 165-b). In some cases, the blocks 185 within a virtual block may have the same block address within their respective planes 180 (e.g., block 185-a may be “block 0” of plane 180-a, block 185-b may be “block 0” of plane 180-b, and so on). In some cases, performing concurrent operations in different planes 180 may be subject to one or more restrictions, such as concurrent operations being performed on memory cells within different pages 190 that have the same page address within their respective planes 180 (e.g., related to command decoding, page address decoding circuitry, or other circuitry being shared across planes 180).

In some cases, a block 185 may include memory cells organized into rows (pages 190) and columns (e.g., strings, not shown). For example, memory cells in the same page 190 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 190 may be the smallest unit of memory (e.g., set of memory cells) that may be independently programmed or read (e.g., programed or read concurrently as part of a single program or read operation), and a block 185 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 190 may, in some cases, not be updated until the entire block 185 that includes the page 190 has been erased.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

Various techniques have been implemented to decrease the packaging size (e.g., a physical size) of memory devices (e.g., the memory devices 145, the memory devices 165). In some cases, to decrease the packaging size of memory devices (e.g., the memory devices 145, the memory devices 165), a memory device may be manufactured to include a stacked memory structure where multiple semiconductor wafers are stacked (e.g., stacked on top of one another). To manufacture the stacked memory devices, various operations may be performed to deposit and bond multiple layers together, and dicing processes may be performed on the bonded layers to singulate the layers into memory chips (e.g., individual stacked memory structures). However, conventional dicing processes, such as blade dicing, may be difficult to implement due to inefficiencies and potential ineffectiveness associated with cutting through multiple layers of material (e.g., splintering of materials, incomplete cuts, crushing of layers). Additionally, some stacked memory architectures may include multiple types of memory (e.g., NAND memory, DRAM memory, volatile memory, non-volatile memory) within a single structure, and each type of memory may be associated with different crystal structures and varying wafer thicknesses. An increase in thickness and density of a memory structure associated with use of multiple memory types in a single memory architecture may result in additional difficulties when performing blade dicing operations (e.g., it may be difficult to cut through a stacked memory structure using blade dicing techniques).

To reduce memory device (e.g., the memory devices 145, the memory devices 165) packaging sizes while increasing effectiveness of singulation operations, a manufacturing process in which stealth dicing operations may be performed multiple times may be implemented. For example, a first stealth dicing operation may be performed on a first semiconductor wafer of a semiconductor wafer stack. An operation may be performed on the first semiconductor wafer to remove a portion of the wafer, and the reduced stack may be rotated (e.g., flipped over) and mounted on DAF (e.g., the first semiconductor wafer may be mounted on the DAF). A second stealth dicing operation may then be performed on a second semiconductor wafer of the semiconductor wafer stack, such that the semiconductor wafer stack may be singulated (e.g., formed into individual memory chips). Performing multiple stealth dicing operations on semiconductor wafer stack to singulate memory chips may enable various combinations of memory within a single memory chip, while also increasing efficiency and effectiveness of chip singulation operations.

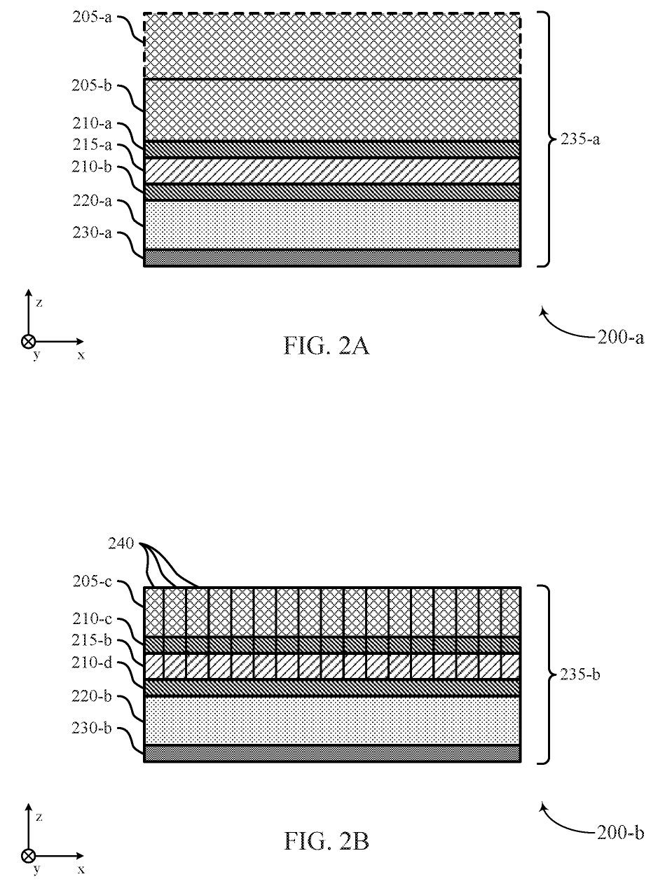

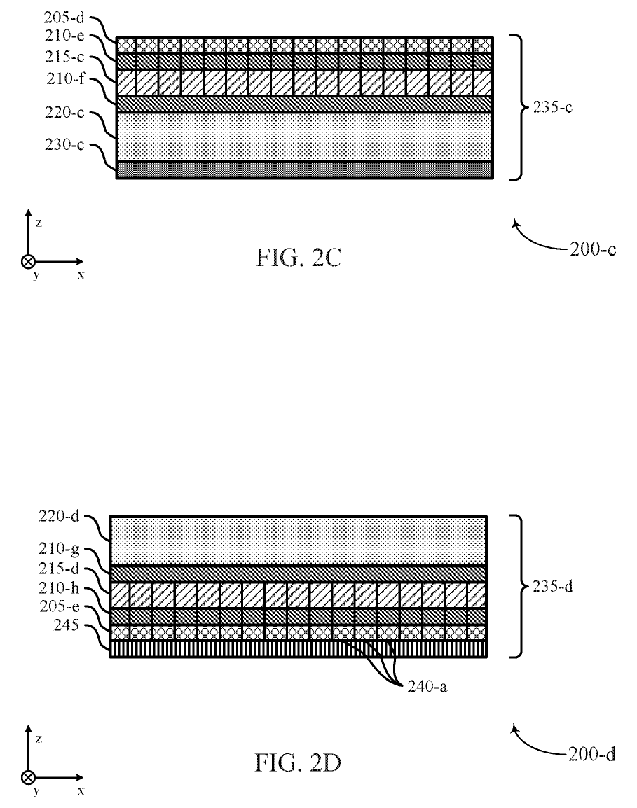

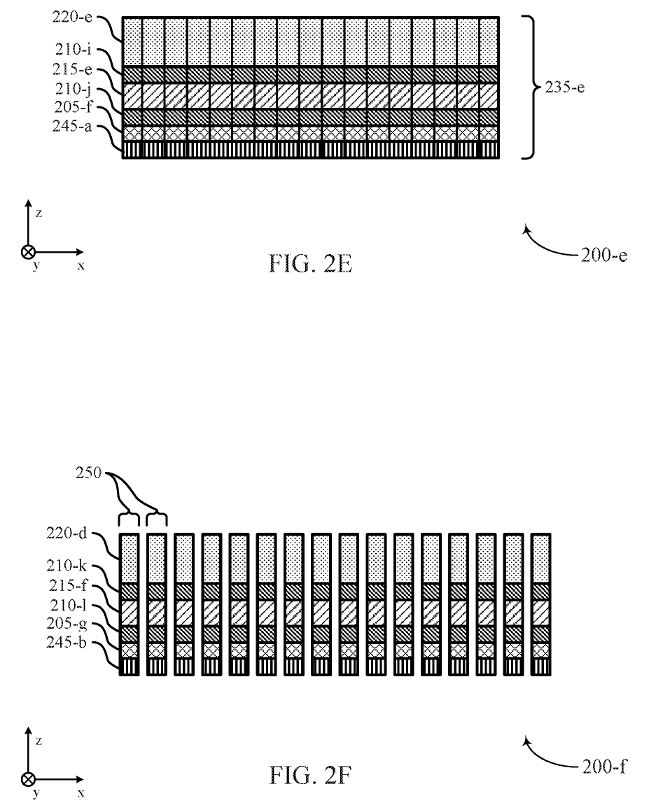

FIGS. 2A through 2F illustrate examples of processing steps 200 that support dual side stealth dicing for forming memory chips in accordance with examples as disclosed herein. For example, FIGS. 2A through 2F may illustrate aspects of a sequence of manufacturing operations for fabricating aspects of a memory device (e.g., a portion of a memory device 145, a portion of a memory device 165). Each view of the FIGS. 2A through 2F may be described with reference to an x-direction, a y-direction, and a z-direction, as illustrated. The manufacturing operations are associated with various cross-sectional views of the processing steps 200. For example, the manufacturing operations illustrate cross-sectional views of the processing steps 200 in an xz-plane. Although the processing steps 200 illustrate examples of certain relative dimensions and quantities of various features, aspects of the processing steps 200 may be implemented with other relative dimensions or quantities of such features in accordance with examples as disclosed herein.

Operations described with reference to FIGS. 2A through 2F may be performed by a manufacturing system, such as a semiconductor fabrication system configured to perform additive operations such as deposition or bonding, subtractive operations such as grinding, blade dicing, stealth dicing, etching, trenching, planarizing, or polishing, and supporting operations such as taping, masking, patterning, photolithography, or aligning, among other operations that support the described techniques. In some examples, operations performed by such a manufacturing system may be supported by a process controller or its components as described herein.

Various techniques have been implemented to decrease the packaging size (e.g., a physical size) of memory devices. In some cases, to decrease the packaging size of memory devices, a memory device may be manufactured to include a stacked memory structure (e.g., one or more memory stack 235) where multiple semiconductor wafers (e.g., a wafer 205, a wafer 220) are stacked (e.g., stacked on top of one another). To manufacture the memory stacks 235, various operations may be performed to deposit and bond multiple layers together, and dicing processes may be performed on the bonded layers to singulate the layers into memory chips (e.g., individual stacked memory structures). However, conventional dicing processes, such as blade dicing, may be difficult to implement. For example, blade dicing may be traditionally used to cut a die-stacked wafer but may be unable to cleanly cut through a full wafer stack.

Additionally, some stacked memory architectures may include multiple types of memory (e.g., NAND memory, DRAM memory, volatile memory, non-volatile memory) within a single structure, and. For example, the wafers 205 may be associated with a first type of memory and the wafers 220 may be associated with a second type of memory. In the case that each type of memory may be associated with different crystal structures and varying wafer thicknesses, the overall thickness and density of a memory stack 235 may be relatively great. An increase in thickness and density of a memory structure associated with use of multiple memory types in a single memory stack 235 may result in additional difficulties when performing blade dicing operations.

To reduce memory device packaging sizes while increasing effectiveness of singulation operations on a memory stack 235, a manufacturing process in which stealth dicing operations may be performed multiple times on a memory stack 235 may be implemented. For example, a first stealth dicing operation may be performed on a first wafer 205 of a memory stack 235. An operation may be performed on the first wafer 205 to remove a portion of the wafer 205, the reduced memory stack 235 may be rotated (e.g., flipped over) and mounted on DAF 230 (e.g., the first wafer 205 may be mounted on the DAF 230). A second stealth dicing operation may then be performed on a second wafer 220 of the memory stack 235, such that the memory stack 235 may be singulated (e.g., formed into individual memory chips 250). Performing multiple stealth dicing operations on the memory stack 235 to singulate memory chips may enable inclusion of various combinations of memory within a single memory chip 250, while also increasing efficiency and effectiveness of chip singulation operations.

FIG. 2A illustrates a portion of a first processing step 200-a that supports dual side stealth dicing for forming memory chips in accordance with examples as disclosed herein. The first processing step 200-a may include applying (e.g., depositing, bonding) DAF 230-a to a memory stack 235-a. For example, the first processing step 200-a may include mounting a stack that includes a wafer 205, a conductive layer 210-a, a bonding layer 215, a conductive layer 210-b, and a wafer 220-a to DAF 230-a such that the memory stack 235-a may include the wafer 205, the conductive layer 210-a, the bonding layer 215, the conductive layer 210-b, the wafer 220-a, and the DAF 230-a. The DAF 230-a may be attached to a surface of the wafer 220-a in the z-direction such that the base of the memory stack 235-a along the z-direction may include the DAF 230-a.

In some examples, the first processing step 200-amay also include a pre-thinning operation during which a z-dimension (e.g., a portion) of the memory stack 235 may be decreased (e.g., removed, reduced). For example, the first processing step 200-amay include grinding the wafer 205 to remove the first wafer 205-a such that the memory stack 235-a may include the second wafer 205-b (e.g., the remaining portion of the wafer 205). The wafer 205 may be ground in the z-direction (e.g., from the top to the bottom of the memory stack 235-a) such that the wafer 205-a is removed from the memory stack 235-a and the wafer 205-b remains in the memory stack 235-a. In some examples, the pre-thinning operation may occur prior to the addition of the DAF 230-a while, in other examples, the pre-thinning operation may occur after the addition of the DAF 230-a.

The wafer 205 may include a first crystal orientation associated with a first type of memory and the wafer 220 may include a second crystal orientation associated with a second type of memory. In some examples, the first crystal orientation and the second crystal orientation may be the same orientation. For example, the first type of memory and the second type of memory may be the same type of memory, such that the wafer 205 and the wafer 220 may both include DRAM memory cells, NAND memory cells, or another type of volatile or non-volatile memory. In some other examples, the first crystal orientation and the second crystal orientation may be different orientations. For example, the first type of memory and the second type of memory may be the same type of memory, such that the wafer 205 and the wafer 220 include DRAM memory cells, NAND memory cells, or another type of volatile or non-volatile memory, in various combinations. In some examples, the wafer 205 may include DRAM memory cells while the wafer 220 may include NAND memory cells. In some examples, the wafer 205 may include NAND memory cells while the wafer 220 may include DRAM memory cells.

A first conductive layer 210 (e.g., the conductive layer 210-a) may be located between (e.g., coupled with, in contact with) the wafer 205-b and the bonding layer 215-a in the z-direction, and a second conductive layer 210 (e.g., the conductive layer 210-b) may be located between (e.g., coupled with, in contact with) the bonding layer 215-b and the wafer 220-a in the z-direction. In some examples, the conductive layer 210 may be example of a layer of a copper material, or another type of conductive material. The bonding layer 215 may be located between (e.g., coupled with, in contact with) the conductive layer 210-a and the conductive layer 210-b in the z-direction. In some cases, the bonding layer 215 may be an example of a non-optically transparent material. For example, the bonding layer 215 may be an example of a material that is not optically transparent for a given SD laser wavelength (e.g., 1090nm). In other examples, the bonding layer 215 may be an example of an optically transparent material. In some examples, the DAF 230 may be example of a dicing tape, or another type of tape used for stabilization in reduction operations associated with the memory stack 235.

FIG. 2B illustrates a portion of a second processing step 200-b that supports dual side stealth dicing for forming memory chips in accordance with examples as disclosed herein. The second processing step 200-bmay include performing a first stealth dicing operation on a memory stack 235. For example, the second processing step 200-bmay include performing a first stealth dicing operation to dice the wafer 205-c, the conductive layer 210-c, and at least a portion of the bonding layer 215-b into diced portions 240 after pre-thinning and adding DAF 230 to the memory stack 235. In some examples, the stealth dicing operation may include focusing a high intensity infrared (IR) laser onto a surface of the memory stack 235 along the z-direction to form cuts in the -z-direction of the memory stack 235 (e.g., from the top down) such that the wafer 205-c, the conductive layer 210-c, and at least a portion of the bonding layer 215-b, are diced.

In some examples, the first stealth dicing operation may also form a stealth dicing modified (SD-MOD) layer at a top portion (e.g., along the z-direction) of the wafer 205 (e.g., not illustrated). The SD-MOD layer may be an example of a portion (e.g., layer) of a wafer that has been affected (e.g., changed, altered) via use of the IR laser in performing a stealth dicing operation. As a result of the second processing step 200-b, the memory stack 235-b may include the diced portions 240 of the wafer 205-c, the conductive layer 210-c, and at least a portion of the bonding layer 215-b located above an undiced conductive layer 210-d, an undiced wafer 220-b, an undiced DAF 230-b, and (in some examples) a remaining, undiced portion of the bonding layer 215-b along the z-direction.

FIG. 2C illustrates a portion of a third processing step 200-c that supports dual side stealth dicing for forming memory chips in accordance with examples as disclosed herein. The third processing step 200-c may include performing a grinding operation on a memory stack 235. For example, the third processing step 200-cmay include performing a grinding operation to reduce a dimension of the memory stack 235-c along the z-direction after performing the first stealth dicing operation. In some examples, the griding operation may include removing portions of a top surface of the memory stack 235 in the -z-direction to remove portions of the diced wafer 205. As a result of the third processing step 200-c, the memory stack 235-c may include diced portions of the wafer 205-d (e.g., reduced portions of the wafer 205-d), the conductive layer 210-e, and at least a portion of the bonding layer 215-c located above an undiced conductive layer 210-f, an undiced wafer 220-c, an undiced DAF 230-c, and (in some examples) a remaining, undiced portion of the bonding layer 215-c along the z-direction. In some examples, the grinding operations may remove the SD-MOD layer from the wafer 205.

FIG. 2D illustrates a portion of a fourth processing step 200-d that supports dual side stealth dicing for forming memory chips in accordance with examples as disclosed herein. The fourth processing step 200-d may include rotating (e.g., flipping) the memory stack 235. For example, the fourth processing step 200-d may include rotating the memory stack 235 (e.g., 180 degrees) such that the wafer 220-d is located above the rest of the layers of the memory stack 235-d along the z-direction and the wafer 205-e may be located at the base of the memory stack 235-d. The fourth processing step 200-dmay also include attaching (e.g., including, adding) tape 245 to the memory stack 235-d. For example, the fourth processing step 200-d may include mounting a memory stack 235 that includes the diced wafer 205-e, the diced conductive layer 210-h, the at least partially diced bonding layer 215-d, the conductive layer 210-g, and the wafer 220-d to tape 245 such that the memory stack 235-d may include the diced wafer 205-e, the diced conductive layer 210-h, the at least partially diced bonding layer 215-d, the conductive layer 210-g, the wafer 220-d, and the tape 245. The tape 245 may be attached to a surface of the portions 240-a (e.g., to a surface of the diced wafer 205-e) in the -z-direction such that the base of the memory stack 235-d along the z-direction may include the tape 245.

FIG. 2E illustrates a portion of a fifth processing step 200-e that supports dual side stealth dicing for forming memory chips in accordance with examples as disclosed herein. The fifth processing step 200-e may include performing a second stealth dicing operation on the memory stack 235. For example, the fifth processing step 200-e may include performing a second stealth dicing operation to dice the wafer 220-e, the conductive layer 210-i, and (in some examples) a remaining portion of the bonding layer 215-e after rotating the memory stack and adding tape 245 to the memory stack 235. In some examples, the stealth dicing operation may include focusing a high intensity IR laser onto a surface of the memory stack 235 along the z-direction to form cuts in the -z-direction of the memory stack 235 (e.g., from the top down) such that all layers of the memory stack 235-e (e.g., the wafer 220-e, the conductive layer 210-i, the bonding layer 215-e, the conductive layer 210-j, the wafer 205-f, and the tape 245-a) are diced along the z-direction. In some examples, the first stealth dicing operation may also form an SD-MD layer at a top portion (e.g., along the z-direction) of the wafer 220.

FIG. 2F illustrates a portion of a sixth processing step 200-f that supports dual side stealth dicing for forming memory chips in accordance with examples as disclosed herein. The sixth processing step 200-f may include performing a singulation operation on the memory stack 235. For example, the sixth processing step 200-f may include performing a singulation operation to separate the diced portions of the wafer 220-d, the conductive layer 210-k, the bonding layer 215-f, the conductive layer 210-l, the wafer 205-g, and the tape 245-b (e.g., in the xy-plane) into memory chips 250 after performing the second stealth dicing operation. The singulation operations may be performed to separate the diced portion of the memory stack 235 in the x-direction such that each resulting memory chip 250 may include a portion of the wafer 220, the conductive layers 210, the bonding layer 215, the wafer 205, and the tape 245, stacked along the z-direction. In some examples, each portion of the wafer 220-d of the memory chips 250 may also include a portion of the SD-MOD layer included in the wafer 220.

Performing multiple stealth dicing operations on a memory stack 235 to singulate (e.g., form) the memory chips 250 may enable the use of multiple wafers within a single memory chip 250 (e.g., multiple types of memory), while also increasing efficiency and effectiveness of chip singulation operations. For example, performing multiple stealth dicing operations may allow for efficient, effective singulation of memory stacks 235 that may include large quantities of layers, regardless of what type of bonding material may be included in the bonding layer 215. Additionally, or alternatively, performing two stealth dicing operations may allow for use of two differing types of wafer orientations within a same memory stack 235 (e.g., and memory chip 250). For example, use of two stealth dicing operations in the manufacturing of the memory chips 250 may allow for both a wafer of DRAM memory cells and a wafer of NAND memory cells to be included in a same memory chip 250 as each stealth dicing operation may be adjusted to account for the crystal structure and orientation of each wafer type. The use of two stealth dicing operations may also enable the effective cutting of wafers that include multiple layers of wafers associated with a same type of memory.

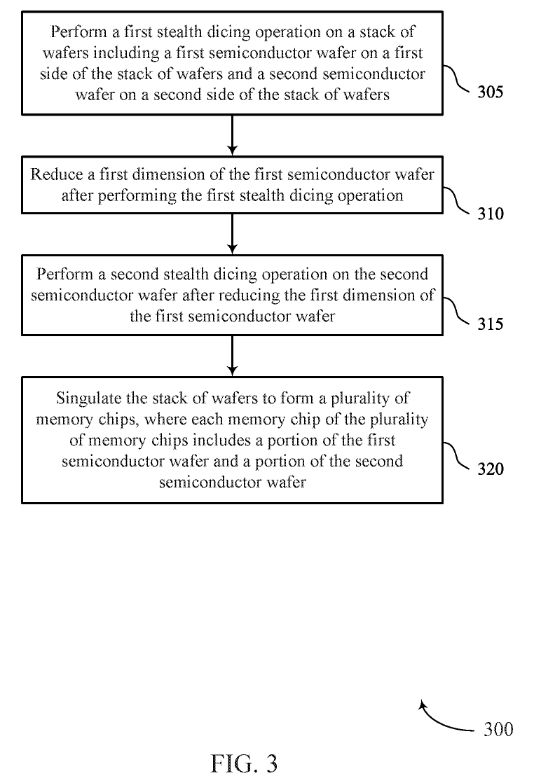

FIG. 3 shows a flowchart illustrating a method 300 that supports dual side stealth dicing for forming memory chips in accordance with examples as disclosed herein. The operations of method 300 may be implemented by a manufacturing system or its components as described herein. In some examples, one or more controllers may execute a set of instructions to control one or more functional elements of the manufacturing system to perform the described functions. Additionally, or alternatively, one or more controllers may perform aspects of the described functions using special-purpose hardware.

At 305, the method may include performing a first stealth dicing operation on a stack of wafers including a first semiconductor wafer on a first side of the stack of wafers and a second semiconductor wafer on a second side of the stack of wafers.

At 310, the method may include reducing a first dimension of the first semiconductor wafer after performing the first stealth dicing operation.

At 315, the method may include performing a second stealth dicing operation on the second semiconductor wafer after reducing the first dimension of the first semiconductor wafer.

At 320, the method may include singulating the stack of wafers to form a plurality of memory chips, where each memory chip of the plurality of memory chips includes a portion of the first semiconductor wafer and a portion of the second semiconductor wafer.

In some examples, an apparatus (e.g., a manufacturing system) as described herein may perform a method or methods, such as the method 300. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing a first stealth dicing operation on a stack of wafers including a first semiconductor wafer on a first side of the stack of wafers and a second semiconductor wafer on a second side of the stack of wafers; reducing a first dimension of the first semiconductor wafer after performing the first stealth dicing operation; performing a second stealth dicing operation on the second semiconductor wafer after reducing the first dimension of the first semiconductor wafer; and singulating the stack of wafers to form a plurality of memory chips, where each memory chip of the plurality of memory chips includes a portion of the first semiconductor wafer and a portion of the second semiconductor wafer.

Aspect 2: The method, apparatus, or non-transitory computer-readable medium of aspect 1, where the first semiconductor wafer includes a first type of memory and the second semiconductor wafer includes a second type of memory.

Aspect 3: The method, apparatus, or non-transitory computer-readable medium of aspect 2, where the first semiconductor wafer includes a first crystal orientation associated with the first type of memory and the second semiconductor wafer includes a second crystal orientation associated with the second type of memory.

Aspect 4: The method, apparatus, or non-transitory computer-readable medium of aspect 3, where the first crystal orientation and the second crystal orientation are different orientations.

Aspect 5: The method, apparatus, or non-transitory computer-readable medium of any of aspects 3 through 4, where the first crystal orientation and the second crystal orientation are a same orientation.

Aspect 6: The method, apparatus, or non-transitory computer-readable medium of any of aspects 1 through 5, where the first semiconductor wafer is located above the second semiconductor wafer in a first direction during the first stealth dicing operation and the method, apparatuses, and non-transitory computer-readable medium further includes operations, features, circuitry, logic, means, or instructions, or any combination thereof for rotating, after reducing the first dimension of the first semiconductor wafer, the stack of wafers such that the second semiconductor wafer is located above the first semiconductor wafer in the first direction, where the second stealth dicing operation is performed after rotating the stack of wafers.

Aspect 7: The method, apparatus, or non-transitory computer-readable medium of any of aspects 1 through 6, further including operations, features, circuitry, logic, means, or instructions, or any combination thereof for taping a first surface of the second semiconductor wafer before performing the first stealth dicing operation and reducing a second dimension of the first semiconductor wafer before performing the first stealth dicing operation.

Aspect 8: The method, apparatus, or non-transitory computer-readable medium of any of aspects 1 through 7, where the stack of wafers includes a bond material located between the first semiconductor wafer and the second semiconductor wafer, the bond material including a non-optically-transparent material.

Aspect 9: The method, apparatus, or non-transitory computer-readable medium of any of aspects 1 through 8, where reducing the first dimension of the first semiconductor wafer includes operations, features, circuitry, logic, means, or instructions, or any combination thereof for grinding a first surface of the first semiconductor wafer.

Aspect 10: The method, apparatus, or non-transitory computer-readable medium of any of aspects 1 through 9, where singulating the stack of wafers to form the plurality of memory chips includes operations, features, circuitry, logic, means, or instructions, or any combination thereof for separating diced portions of the stack of wafers in a second direction.

Aspect 11: The method, apparatus, or non-transitory computer-readable medium of any of aspects 1 through 10, further including operations, features, circuitry, logic, means, or instructions, or any combination thereof for bonding the first semiconductor wafer to a film after reducing the first dimension of the first semiconductor wafer.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 12: A memory device, including: a first semiconductor layer including a first crystal orientation; a bonding material including a first side coupled with the first semiconductor layer; and a second semiconductor layer associated with a second crystal orientation and coupled with a second side of the bonding material, where the second semiconductor layer includes a stealth dicing modified layer.

Aspect 13: The memory device of aspect 12, where the stealth dicing modified layer includes one or more cracks resulting from a stealth dicing operation.

Aspect 14: The memory device of any of aspects 12 through 13, where the first crystal orientation and the second crystal orientation include a same orientation.

Aspect 15: The memory device of any of aspects 12 through 14, where the first crystal orientation and the second crystal orientation include different orientations.

Aspect 16: The memory device of any of aspects 12 through 15, where the bonding material includes a non-optically transparent material.

Aspect 17: The memory device of any of aspects 12 through 16, where the first semiconductor layer and the second semiconductor layer each include a same type of memory.

Aspect 18: The memory device of any of aspects 12 through 17, where the first semiconductor layer and the second semiconductor layer each include a different type of memory.

Aspect 19: The memory device of any of aspects 12 through 18, further including: a film bonded to the second semiconductor layer.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for manufacturing a memory device, comprising:
performing a first stealth dicing operation on a stack of wafers comprising a first semiconductor wafer on a first side of the stack of wafers and a second semiconductor wafer on a second side of the stack of wafers;
reducing a first dimension of the first semiconductor wafer after performing the first stealth dicing operation;
performing a second stealth dicing operation on the second semiconductor wafer after reducing the first dimension of the first semiconductor wafer; and
singulating the stack of wafers to form a plurality of memory chips, wherein each memory chip of the plurality of memory chips comprises a portion of the first semiconductor wafer and a portion of the second semiconductor wafer.

2. The method of claim 1, wherein the first semiconductor wafer comprises a first type of memory and the second semiconductor wafer comprises a second type of memory.

3. The method of claim 2, wherein the first semiconductor wafer comprises a first crystal orientation associated with the first type of memory and the second semiconductor wafer comprises a second crystal orientation associated with the second type of memory.

4. The method of claim 3, wherein the first crystal orientation and the second crystal orientation are different orientations.

5. The method of claim 3, wherein the first crystal orientation and the second crystal orientation are a same orientation.

6. The method of claim 1, wherein the first semiconductor wafer is located above the second semiconductor wafer in a first direction during the first stealth dicing operation, the method further comprising:
rotating, after reducing the first dimension of the first semiconductor wafer, the stack of wafers such that the second semiconductor wafer is located above the first semiconductor wafer in the first direction, wherein the second stealth dicing operation is performed after rotating the stack of wafers.

7. The method of claim 1, further comprising:
taping a first surface of the second semiconductor wafer before performing the first stealth dicing operation; and
reducing a second dimension of the first semiconductor wafer before performing the first stealth dicing operation.

8. The method of claim 1, wherein the stack of wafers comprises a bond material located between the first semiconductor wafer and the second semiconductor wafer, the bond material comprising a non-optically-transparent material.

9. The method of claim 1, wherein reducing the first dimension of the first semiconductor wafer comprises:
grinding a first surface of the first semiconductor wafer.

10. The method of claim 1, wherein singulating the stack of wafers to form the plurality of memory chips comprises:
separating diced portions of the stack of wafers in a second direction.

11. The method of claim 1, further comprising:
bonding the first semiconductor wafer to a film after reducing the first dimension of the first semiconductor wafer.

12. A memory device, comprising:
a first semiconductor layer comprising a first crystal orientation;
a bonding material comprising a first side coupled with the first semiconductor layer; and
a second semiconductor layer associated with a second crystal orientation and coupled with a second side of the bonding material, wherein the second semiconductor layer comprises a stealth dicing modified layer.

13. The memory device of claim 12, wherein the stealth dicing modified layer comprises one or more cracks resulting from a stealth dicing operation.

14. The memory device of claim 12, wherein the first crystal orientation and the second crystal orientation comprise a same orientation.

15. The memory device of claim 12, wherein the first crystal orientation and the second crystal orientation comprise different orientations.

16. The memory device of claim 12, wherein the bonding material comprises a non-optically transparent material.

17. The memory device of claim 12, wherein the first semiconductor layer and the second semiconductor layer each comprise a same type of memory.

18. The memory device of claim 12, wherein the first semiconductor layer and the second semiconductor layer each comprise a different type of memory.

19. The memory device of claim 12, further comprising:
a film bonded to the second semiconductor layer.

20. A memory device, comprising:
a first semiconductor wafer on a first side of a stack of wafers, the first semiconductor wafer comprising a first semiconductor layer comprising a first crystal orientation;
a bonding material comprising a first side coupled with the first semiconductor layer; and
a second semiconductor wafer on a second side of the stack of wafers, the second semiconductor wafer comprising a second semiconductor layer associated with a second crystal orientation and coupled with a second side of the bonding material, wherein the second semiconductor layer comprises a stealth dicing modified layer, wherein the memory device is formed by:
performing a first stealth dicing operation on the stack of wafers;
reducing a first dimension of the first semiconductor wafer after performing the first stealth dicing operation;
performing a second stealth dicing operation on the second semiconductor wafer after reducing the first dimension of the first semiconductor wafer; and
singulating the stack of wafers to form a plurality of memory devices, wherein the memory device of the plurality of memory devices comprises a portion of the first semiconductor wafer and a portion of the second semiconductor wafer.

21. The memory device of claim 20, wherein the first semiconductor wafer comprises a first type of memory and the second semiconductor wafer comprises a second type of memory.

22. The memory device of claim 20, wherein the first crystal orientation and the second crystal orientation are different orientations.

23. The memory device of claim 20, wherein the first crystal orientation and the second crystal orientation are a same orientation.

24. The memory device of claim 20, wherein the stealth dicing modified layer comprises one or more cracks resulting from a stealth dicing operation.

25. The memory device of claim 20, wherein the first semiconductor wafer is located above the second semiconductor wafer in a first direction during the first stealth dicing operation, wherein the memory device is further formed by:
rotating, after reducing the first dimension of the first semiconductor wafer, the stack of wafers such that the second semiconductor wafer is located above the first semiconductor wafer in the first direction, wherein the second stealth dicing operation is performed after rotating the stack of wafers.
